(19) United States
(12) Patent Application Publication
(10) Pub. No.: US 2025/0062279 A1
(43) Pub. Date: Feb. 20, 2025

(54) SEMICONDUCTOR PACKAGE AND METHOD OF FABRICATING THE SAME

(71) Applicant: Samsung Electronics Co., Ltd., Suwon-si (KR)

(72) Inventors: Sunggu KANG, Suwon-si (KR); Jae Choon KIM, Suwon-si (KR); Sung-Ho MUN, Suwon-si (KR); Hwanjoo PARK, Suwon-si (KR)

(73) Assignee: Samsung Electronics Co., Ltd., Suwon-si (KR)

(21) Appl. No.: 18/594,300

(22) Filed: Mar. 4, 2024

(30) Foreign Application Priority Data
Aug. 18, 2023 (KR) 10-2023-0108377

(51) Int. Cl. H01L 25/065; H01L 23/00; H01L 23/13; H01L 23/31; H01L 23/48; H01L 23/522; H01L 25/18

(52) U.S. Cl. CPC H01L 25/0652; H01L 23/13; H01L 23/31; H01L 23/481; H01L 23/5226; H01L 23/562; H01L 24/16; H01L 24/32; H01L 24/73; H01L 25/18; H01L 2224/16147; H01L 2224/16227; H01L 2224/32225; H01L 2224/73203; H01L 2924/1431; H01L 2924/181

(57) ABSTRACT

Disclosed is a semiconductor package comprising an interposer, a first semiconductor die below the interposer, and a first dummy die, a second dummy die, and a second semiconductor die over the interposer. The first semiconductor die, the second semiconductor die, the first dummy die, and the second dummy die overlap the interposer. The first semiconductor die overlaps the second semiconductor die. The second semiconductor die is between the first dummy die and the second dummy die.

### CROSS-REFERENCE TO RELATED APPLICATION

This U.S. nonprovisional application claims priority under 35 U.S.C § 119 to Korean Patent Application No. 10-2023-0108377 filed on Aug. 18, 2023 in the Korean Intellectual Property Office, the disclosure of which is hereby incorporated by reference in its entirety.

### BACKGROUND

The present inventive concepts relate to semiconductor packages, and more particularly, to semiconductor packages including an interposer and methods of fabricating the same.

A semiconductor package is provided to implement an integrated circuit chip to qualify for use in electronic products. Typically, a semiconductor package is configured such that a semiconductor chip is mounted on a printed circuit board (PCB) and bonding wires or bumps are used to electrically connect the semiconductor chip to the printed circuit board. With the development of electronic industry, various studies have been conducted to improve reliability and durability of semiconductor packages.

### SUMMARY

Some example embodiments of the present inventive concepts provide a semiconductor package with improved electrical properties and increased reliability.

According to some example embodiments of the present inventive concepts, a semiconductor package may include an interposer; a first semiconductor die below the interposer; and a first dummy die, a second dummy die, and a second semiconductor die over the interposer. The first semiconductor die, the second semiconductor die, the first dummy die, and the second dummy die may overlap the interposer. The first semiconductor die may overlap the second semiconductor die. The second semiconductor die may be between the first dummy die and the second dummy die.

According to some example embodiments of the present inventive concepts, a semiconductor package may include an interposer; a first semiconductor die below the interposer; and a first dummy die, a second dummy die, and a second semiconductor die over the interposer. The second semiconductor die may be between the first dummy die and the second dummy die. A width of the interposer may be greater than a sum of a width of the first dummy die, a width of the second dummy die, and a width of the second semiconductor die. The width of the interposer may be greater than a width of the first semiconductor die.

According to some example embodiments of the present inventive concepts, a semiconductor package may include a package substrate; a stiffener in contact with the package substrate; a first semiconductor die over the package substrate; an interposer over the first semiconductor die; a first dummy die, a second dummy die, a third dummy die, a fourth dummy die, and a plurality of second semiconductor dies over the interposer; a first molding layer surrounding the first semiconductor die; and a second molding layer surrounding the first to fourth dummy dies and the second semiconductor dies. The second semiconductor dies may be between the first and second dummy dies. The first and second dummy dies and the second semiconductor dies may be between the third and fourth dummy dies.

According to some example embodiments of the present inventive concepts, a method of fabricating a semiconductor package may include connecting a first semiconductor die to a bottom surface of an interposer; connecting a second semiconductor die, a first dummy die, and a second dummy die to a top surface of the interposer; forming a stiffener on a package substrate; and connecting the first semiconductor die to the package substrate. A width of the interposer may be greater than a width of the first semiconductor die. The second semiconductor die may be between the first dummy die and the second dummy die.

### BRIEF DESCRIPTION OF DRAWINGS

FIG. 1 illustrates a plan view showing a semiconductor package according to some example embodiments.

FIG. 2 illustrates a cross-sectional view taken along line A-A′ of FIG. 1.

FIG. 3 illustrates an enlarged view showing section E of FIG. 2.

FIG. 4 illustrates a plan view showing a stiffener.

FIGS. 5, 6, 7, and 8 illustrate cross-sectional views showing a method of fabricating a semiconductor package according to some example embodiments.

FIG. 9 illustrates an enlarged cross-sectional view showing a semiconductor package according to some example embodiments.

FIG. 10 illustrates an enlarged cross-sectional view showing a semiconductor package according to some example embodiments.

FIG. 11 illustrates a cross-sectional view showing a semiconductor package according to some example embodiments.

FIG. 12 illustrates a cross-sectional view showing a semiconductor package according to some example embodiments.

FIG. 13 illustrates a cross-sectional view showing a semiconductor package according to some example embodiments.

FIG. 14 illustrates a cross-sectional view showing a semiconductor package according to some example embodiments.

### DETAILED DESCRIPTION

The following will describe in detail semiconductor packages and fabrication methods thereof according to some example embodiments of the present inventive concepts in conjunction with the accompanying drawings.

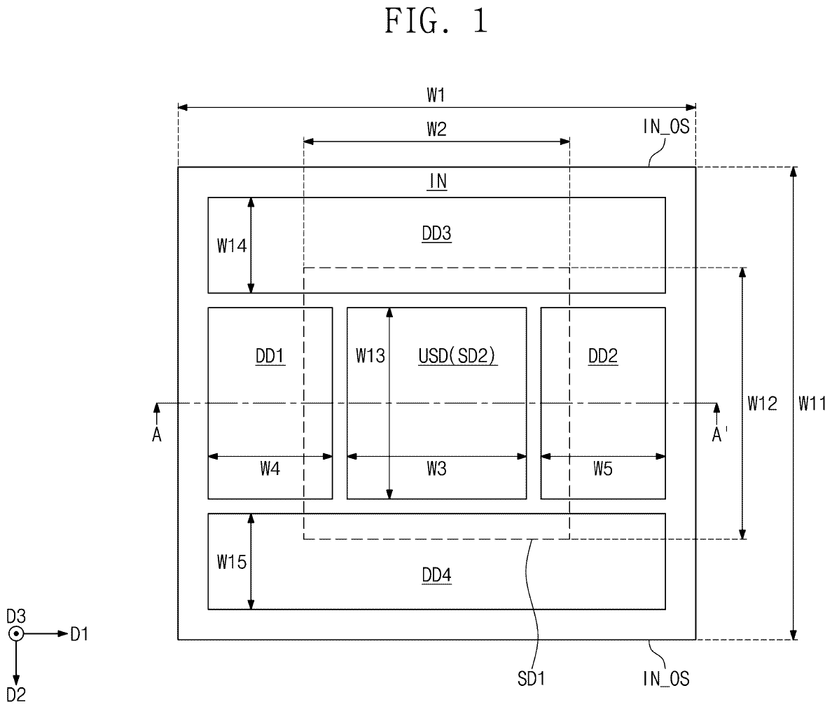

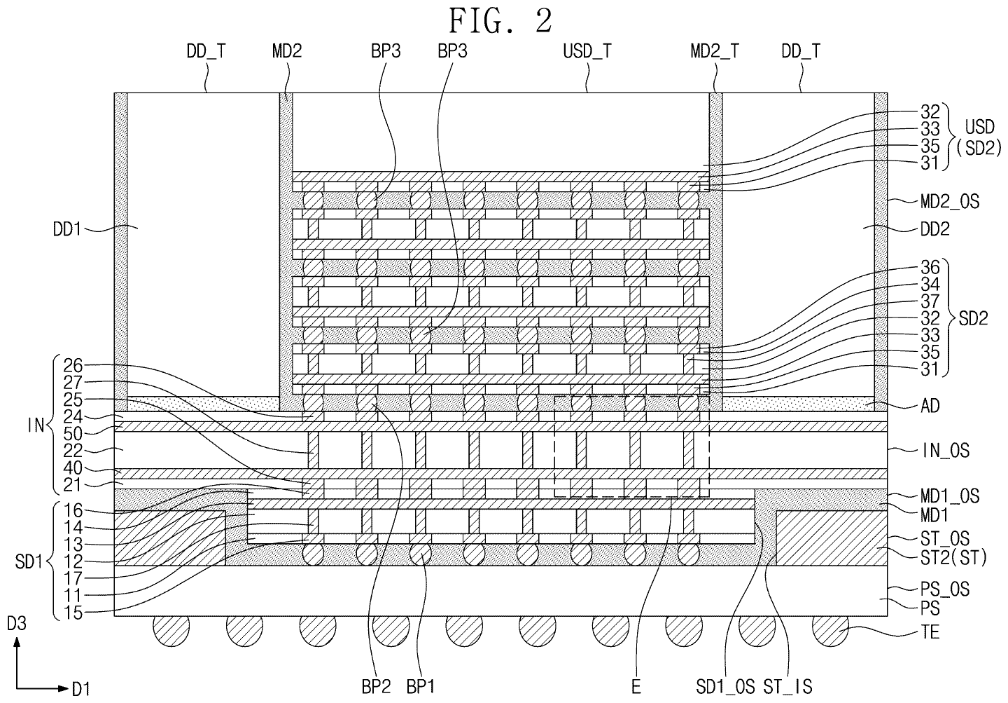

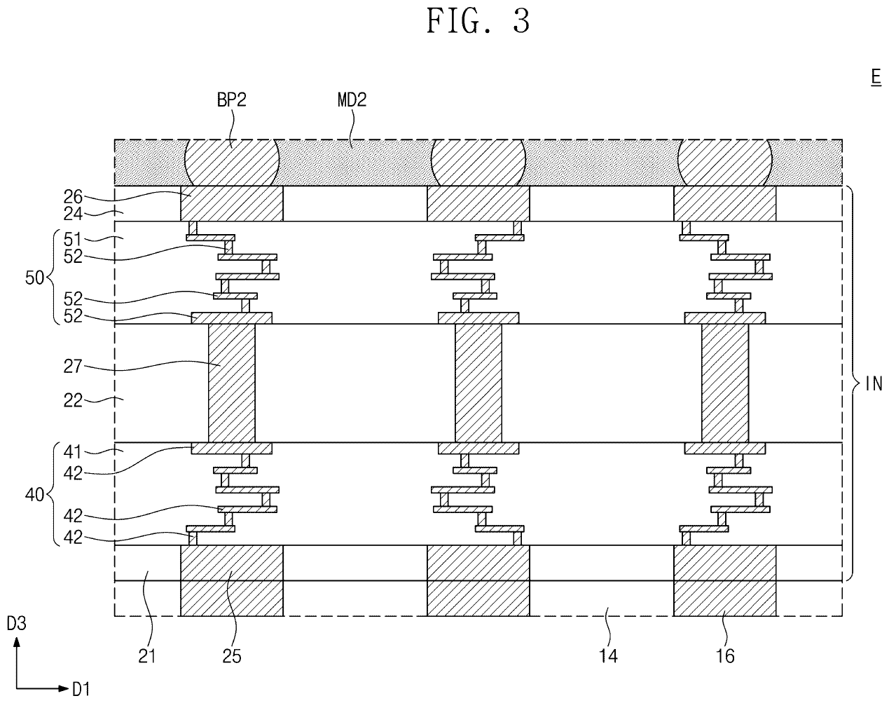

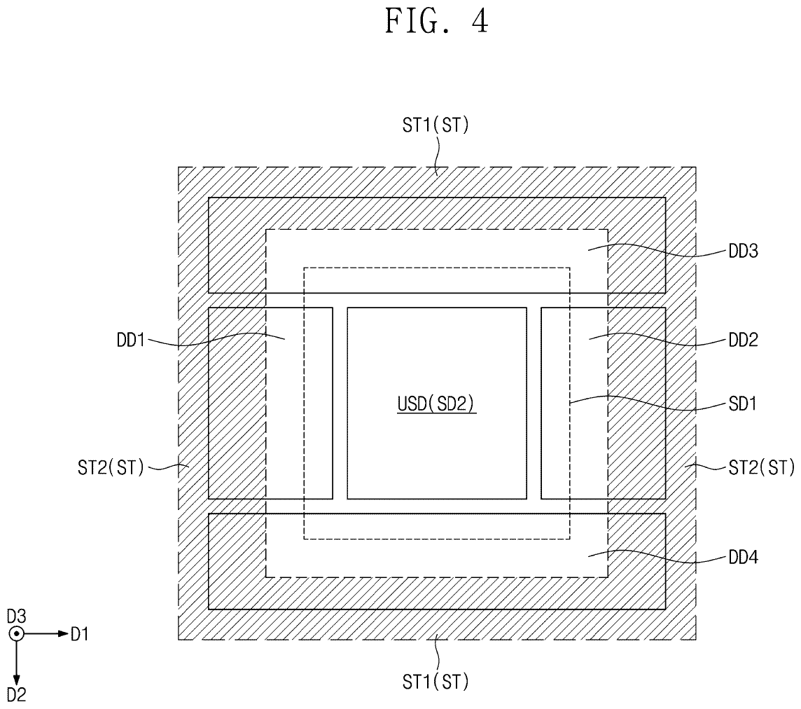

FIG. 1 illustrates a plan view showing a semiconductor package according to some example embodiments. FIG. 2 illustrates a cross-sectional view taken along line A-A′ of FIG. 1. FIG. 3 illustrates an enlarged view showing section E of FIG. 2. FIG. 4 illustrates a plan view showing a stiffener.

Referring to FIGS. 1 and 2, a semiconductor package may include terminals TE, a package substrate PS, a stiffener ST, a first molding layer MD1, first bumps BP1, second bumps BP2, third bumps BP3, a first semiconductor die SD1, an interposer IN, second semiconductor dies SD2, a first dummy die DD1, a second dummy die DD2, a third dummy die DD3, a fourth dummy die DD4, adhesive layers AD, and a second molding layer MD2.

The stiffener ST may be provided on the package substrate PS. The stiffener ST may be in contact with a top surface of the package substrate PS. The terminals TE may be provided below the package substrate PS. The semiconductor package may be electrically connected through the terminals TE to an external apparatus.

In some example embodiments, the package substrate PS may be a printed circuit board (PCB). The stiffener ST may serve to prevent warpage of the package substrate PS. The stiffener ST may include a conductive material. For example, the stiffener ST may include at least one selected from copper, aluminum, and stainless steels. The terminals TE may include a conductive material.

The first semiconductor die SD1 may be provided on (or over) the package substrate PS. The stiffener ST may surround at least a portion of the first semiconductor die SD1. An upper portion of the stiffener ST and a lower portion of the first semiconductor die SD1 may be located at substantially the same or the same level. The first semiconductor die SD1 may include a first lower protection layer 11, a first substrate 12 on the first lower protection layer 11, a first wiring structure 13 on the first substrate 12, a first upper protection layer 14 on the first wiring structure 13, first lower pads 15 in the first lower protection layer 11, first upper pads 16 in the first upper protection layer 14, and first through vias 17 that penetrate the first substrate 12. In some example embodiments, the first wiring structure 13 may be provided between the first lower protection layer 11 and the first substrate 12.

The first substrate 12 may have a plate shape elongated along a plane defined in a first direction D1 and a second direction D2. The first direction D1 and the second direction D2 may intersect each other. For example, the first direction D1 and the second direction D2 may be horizontal directions that are orthogonal to each other. The first substrate 12 may be a semiconductor substrate. For example, the first substrate 12 may include silicon, germanium, silicon-germanium, gallium-phosphorus, or gallium-arsenic. In some example embodiments, the first substrate 12 may be a silicon-on-insulator (SOI) substrate or a germanium-on-insulator (GOI) substrate.

The first lower protection layer 11 may include a dielectric material. For example, the first lower protection layer 11 may include oxide. In some example embodiments, the first lower protection layer 11 may be a multiple layer including a plurality of dielectric layers.

The first upper protection layer 14 may include a dielectric material. For example, the first upper protection layer 14 may include oxide. In some example embodiments, the first upper protection layer 14 may be a multiple layer including a plurality of dielectric layers.

The first lower pads 15 may be surrounded by the first lower protection layer 11. The first lower pads 15 may include a conductive material. For example, the first lower pads 15 may include copper.

The first upper pads 16 may be surrounded by the first upper protection layer 14. The first upper pads 16 may include a conductive material. For example, the first upper pads 16 may include copper.

The first through via 17 may be connected to the first lower pad 15 and the first wiring structure 13. The first through via 17 may penetrate in a third direction D3 through the first substrate 12 to electrically connect the first lower pad 15 to the first wiring structure 13. The third direction D3 may intersect the first direction D1 and the second direction D2. For example, the third direction D3 may be a vertical direction perpendicular to the first direction D1 and the second direction D2. The first through via 17 may include a conductive material.

The first semiconductor die SD1 may further include a semiconductor device. For example, the first semiconductor die SD1 may be a logic semiconductor die including a logic semiconductor device. The logic semiconductor die may be, for example, a central processing unit (CPU), a graphic processing unit (GPU), or an application processor (AP).

The first bumps BP1 may be provided between the first semiconductor die SD1 and the package substrate PS. The first bumps BP1 may electrically connect the first semiconductor die SD1 to the package substrate PS. The first bump BP1 may be in contact with the first lower pad 15. The first bumps BP1 may include a conductive material.

The interposer IN may be provided on (or over) the first semiconductor die SD1. The interposer IN may overlap in the third direction D3 with the first semiconductor die SD1. The first semiconductor die SD1 may be provided below the interposer IN. A top surface of the first semiconductor die SD1 may be in contact with a bottom surface of the interposer IN. The interposer IN may include a second lower protection layer 21, a lower wiring structure 40 on the second lower protection layer 21, a second substrate 22 on the lower wiring structure 40, an upper wiring structure 50 on the second substrate 22, a second upper protection layer 24 on the upper wiring structure 50, second lower pads 25 in the second lower protection layer 21, second upper pads 26 in the second upper protection layer 24, and second through vias 27 that penetrate the second substrate 22. The bottom surface of the interposer IN may face a top surface of the stiffener ST.

The second substrate 22 may be a semiconductor substrate. In some example embodiments, the second substrate 22 may be a silicon-on-insulator (SOI) substrate or a germanium-on-insulator (GOI) substrate.

The second lower protection layer 21 may include a dielectric material. In some example embodiments, the second lower protection layer 21 may be a multiple layer including a plurality of dielectric layers. The second upper protection layer 24 may include a dielectric material. In some example embodiments, the second upper protection layer 24 may be a multiple layer including a plurality of dielectric layers.

The second lower pads 25 may be surrounded by the second lower protection layer 21. The second lower pads 25 may include a conductive material. For example, the second lower pads 25 may include copper. The second upper pads 26 may be surrounded by the second upper protection layer 24. The second upper pads 26 may include a conductive material. For example, the second upper pads 26 may include copper.

The second through via 27 may connect the lower wiring structure 40 to the upper wiring structure 50. The second through via 27 may penetrate in the third direction D3 through the second substrate 22 to electrically connect the lower wiring structure 40 to the upper wiring structure 50. The second through via 27 may include a conductive material.

A hybrid wafer bonding process may be employed to bond the interposer IN to the first semiconductor die SD1. A bottom surface of the second lower pad 25 may be in contact with a top surface of the first upper pad 16. A bottom surface of the second lower protection layer 21 may be in contact with a top surface of the first upper protection layer 14. In some example embodiments, the interposer IN and the first semiconductor die SD1 may be electrically connected through bumps therebetween.

The first molding layer MD1 may be provided between the package substrate PS and the interposer IN. The first molding layer MD1 may include a portion interposed between the stiffener ST and the interposer IN, a portion interposed between the stiffener ST and the first semiconductor die SD1, and a portion interposed between the package substrate PS and the first semiconductor die SD1. The first molding layer MD1 may surround the first semiconductor die SD1. The first molding layer MD1 may be in contact with the top surface of the stiffener ST, an inner sidewall ST_IS of the stiffener ST, an outer sidewall SD1_OS of the first semiconductor die SD1, the top surface of the package substrate PS, and the bottom surface of the interposer IN. The first molding layer MD1 may include a polymeric material. For example, the first molding layer MD1 may include an epoxy resin.

The second semiconductor dies SD2 may be provided on (or over) the interposer IN. The second semiconductor dies SD2 may overlap each other in the third direction D3. The second semiconductor dies SD2 may overlap in the third direction D3 with the interposer IN and the first semiconductor die SD1. The second semiconductor die SD2 may include a third lower protection layer 31, a second wiring structure 33 on the third lower protection layer 31, a third substrate 32 on the second wiring structure 33, a third upper protection layer 34 on the third substrate 32, third lower pads 35 in the third lower protection layer 31, third upper pads 36 in the third upper protection layer 34, and third through vias 37 that penetrate the third substrate 32. In some example embodiments, the second wiring structure 33 may be provided between the third substrate 32 and the third upper protection layer 34.

The third substrate 32 may be a semiconductor substrate. In some example embodiments, the third substrate 32 may be a silicon-on-insulator (SOI) substrate or a germanium-on-insulator (GOI) substrate.

The third lower protection layer 31 may include a dielectric material. In some example embodiments, the third lower protection layer 31 may be a multiple layer including a plurality of dielectric layers. The third upper protection layer 34 may include a dielectric material. In some example embodiments, the third upper protection layer 34 may be a multiple layer including a plurality of dielectric layers.

The third lower pads 35 may be surrounded by the third lower protection layer 31. The third lower pads 35 may include a conductive material. For example, the third lower pads 35 may include copper. The third upper pads 36 may be surrounded by the third upper protection layer 34. The third upper pads 36 may include a conductive material. For example, the third upper pads 36 may include copper.

The third through via 37 may connect the second wiring structure 33 to the third upper pad 36. The third through via 37 may penetrate in the third direction D3 through the third substrate 32 to electrically connect the second wiring structure 33 to the third upper pad 36. The third through via 37 may include a conductive material.

The second semiconductor die SD2 may further include a semiconductor device. For example, the second semiconductor die SD2 may be a memory semiconductor die including a memory semiconductor device. The memory semiconductor device may be, for example, a dynamic random access memory (DRAM) semiconductor device, a static RAM (SRAM) semiconductor device, a thyristor RAM (TRAM) semiconductor device, a zero capacitor RAM (ZRAM) semiconductor device, a twin transistor RAM (TTRAM) semiconductor device, a Flash memory semiconductor device, a magnetic RAM (MRAM) semiconductor device, a spin-transfer torque RAM (STT-MRAM) semiconductor device, a ferroelectric RAM (FRAM) semiconductor device, a phase change RAM (PRAM) semiconductor device, a polymer RAM, or an insulator resistance change memory semiconductor device.

An uppermost semiconductor die USD may be positioned at top of the second semiconductor dies SD2. The uppermost semiconductor die USD may include none of the third upper protection layer 34, the third upper pad 36, and the third through via 37.

The second bump BP2 may be provided between the second semiconductor die SD2 and the interposer IN. The second bump BP2 may electrically connect the second semiconductor die SD2 to the interposer IN. The second bump BP2 may be in contact with the second upper pad 26 and the third lower pad 35. The second bump BP2 may include a conductive material.

The third bump BP3 may be provided between the second semiconductor dies SD2. The third bump BP3 may electrically connect the second semiconductor dies SD2 to each other. The third bump BP3 may be in contact with the third upper pad 36 and the third lower pad 35. The third bump BP3 may include a conductive material.

The first dummy die DD1, the second dummy die DD2, the third dummy die DD3, and the fourth dummy die DD4 may be provided on (or over) the interposer IN. The first, second, third, and fourth dummy dies DD1, DD2, DD3, and DD4 may overlap in the third direction D3 with the interposer IN. Each of the first, second, third, and fourth dummy dies DD1, DD2, DD3, and DD4 may include a portion that overlaps in the third direction D3 with a portion of the first semiconductor die SD1.

The first, second, third, and fourth dummy dies DD1, DD2, DD3, and DD4 may be spaced apart from the second semiconductor dies SD2. The first and second dummy dies DD1 and DD2 may be spaced apart in the first direction D1 from the second semiconductor dies SD2. The third and fourth dummy dies DD3 and DD4 may be spaced apart in the second direction D2 from the second semiconductor dies SD2, the first dummy die DD1, and the second dummy die DD2.

Each of the first, second, third, and fourth dummy dies DD1, DD2, DD3, and DD4 may include no semiconductor device. Each of the first, second, third, and fourth dummy dies DD1, DD2, DD3, and DD4 may include bulk silicon or bulk metal (e.g., bulk copper or bulk aluminum). For example, the first dummy die DD1 may be a bulk silicon block formed as a whole of silicon or a bulk metal block (e.g., a bulk copper block or a bulk aluminum block) formed as a whole of metal.

A width W1 in the first direction D1 of the interposer IN may be greater than a width W2 in the first direction D1 of the first semiconductor die SD1. The width W1 in the first direction D1 of the interposer IN may be about or exactly 1 mm to about or exactly 90 mm greater than the width W2 in the first direction D1 of the first semiconductor die SD1. The width W1 in the first direction D1 of the interposer IN may be greater than a sum of a width W3 in the first direction D1 of the second semiconductor die SD2, a width W4 in the first direction D1 of the first dummy die DD1, and a width W5 in the first direction D1 of the second dummy die DD2. The width W1 in the first direction D1 of the interposer IN may be about or exactly 1 mm to about or exactly 90 mm greater than the width W3 in the first direction D1 of the second semiconductor die SD2. The width W1 in the first direction D1 of the interposer IN may be greater than a width in the first direction D1 of the third dummy die DD3 and a width in the first direction D1 of the fourth dummy die DD4.

A width W11 in the second direction D2 of the interposer IN may be greater than a width W12 in the second direction D2 of the first semiconductor die SD1. The width W11 in the second direction D2 of the interposer IN may be about or exactly 1 mm to about or exactly 90 mm greater than the width W12 in the second direction D2 of the first semiconductor die SD1. The width W11 in the second direction D2 of the interposer IN may be greater than a sum of a width W13 in the second direction D2 of the second semiconductor die SD2, a width W14 in the second direction D2 of the third dummy die DD3, and a width W15 in the second direction D2 of the fourth dummy die DD4. The width W11 in the second direction D2 of the interposer IN may be about or exactly 1 mm to about or exactly 90 mm greater than the width W13 in the second direction D2 of the second semiconductor die SD2. The width W11 in the second direction D2 of the interposer IN may be greater than a width in the second direction D2 of the first dummy die DD1 and a width in the second direction D2 of the second dummy die DD2.

The width W1 in the first direction D1 of the interposer IN may be substantially the same or the same as a width in the first direction D1 of the package substrate PS. In some example embodiments, the width W1 in the first direction D1 of the interposer IN may be less than the width in the first direction D1 of the package substrate PS.

The width W11 in the second direction D2 of the interposer IN may be substantially the same or the same as a width in the second direction D2 of the package substrate PS. In some example embodiments, the width W11 in the second direction D2 of the interposer IN may be less than the width in the second direction D2 of the package substrate PS.

The first, second, third, and fourth dummy dies DD1, DD2, DD3, and DD4 may have their top surfaces DD_T coplanar with a top surface USD_T of the uppermost semiconductor die USD and a top surface MD2_T of the second molding layer MD2. The top surfaces DD_T of the first, second, third, and fourth dummy dies DD1, DD2, DD3, and DD4 may be located at substantially the same or the same level as that of the top surface USD_T of the uppermost semiconductor die USD and that of the top surface MD2_T of the second molding layer MD2. A distance in the third direction D3 between the interposer IN and the top surfaces DD_T of the first, second, third, and fourth dummy dies DD1, DD2, DD3, and DD4 may be substantially the same or the same as a distance in the third direction D3 between the interposer IN and the top surface USD_T of the uppermost semiconductor die USD and a distance in the third direction D3 between the interposer IN and the top surface MD2_T of the second molding layer MD2.

Each of the first, second, third, and fourth dummy dies DD1, DD2, DD3, and DD4 may have a height greater than that of each of the second semiconductor dies SD2, that of the interposer IN, and that of the first semiconductor die SD1. A length in the third direction D3 of each of the first, second, third, and fourth dummy dies DD1, DD2, DD3, and DD4 may be greater than a length in the third direction D3 of each of the second semiconductor dies SD2, a length in the third direction D3 of the interposer IN, and a length in the third direction D3 of the first semiconductor die SD1.

The adhesive layer AD may be provided between the interposer IN and each of the first, second, third, and fourth dummy dies DD1, DD2, DD3, and DD4. Each of the first, second, third, and fourth dummy dies DD1, DD2, DD3, and DD4 may be attached through the adhesive layer AD to the interposer IN. The adhesive layer AD may include a polymeric material.

The second molding layer MD2 may be provided to surround the first, second, third, and fourth dummy dies DD1, DD2, DD3, and DD4, the adhesive layers AD, and the second semiconductor dies SD2. The second molding layer MD2 may include a portion interposed between the second semiconductor die SD2 and the dummy dies DD1, DD2, DD3, and DD4 and a portion interposed between the dummy dies DD1, DD2, DD3, and DD4. The second molding layer MD2 may include a polymeric material. For example, the second molding layer MD2 may include an epoxy resin.

In some example embodiments, the interposer IN may have an outer sidewall IN_OS coplanar with an outer sidewall MD2_OS of the second molding layer MD2, an outer sidewall MD1_OS of the first molding layer MD1, an outer sidewall ST_OS of the stiffener ST, and an outer sidewall PS_OS of the package substrate PS.

When viewed in plan as shown in FIG. 1, the first and second semiconductor dies SD1 and SD2 and the first, second, third, and fourth dummy dies DD1, DD2, DD3, and DD4 may be disposed between the outer sidewalls IN_OS of the interposer IN that extend in the first direction D1.

Referring to FIG. 3, the lower wiring structure 40 of the interposer IN may include a lower wiring dielectric layer 41 and lower conductive structures 42 in the lower wiring dielectric layer 41. The lower wiring dielectric layer 41 may be provided on the second lower protection layer 21. The lower wiring dielectric layer 41 may be in contact with a top surface of the second lower protection layer 21 and a bottom surface of the second substrate 22. The lower wiring dielectric layer 41 may include a dielectric material. In some example embodiments, the lower wiring dielectric layer 41 may be a multiple dielectric layer including a plurality of dielectric layers.

The lower conductive structures 42 may be surrounded by the lower wiring dielectric layer 41. Each of the lower conductive structures 42 may be a conductive pad, a conductive line, or a conductive via. The lower conductive structures 42 may be connected to each other. The second through via 27 and the second lower pad 25 may be electrically connected through the lower conductive structures 42. The lower conductive structures 42 may include a conductive material.

The upper wiring structure 50 of the interposer IN may include an upper wiring dielectric layer 51 and upper conductive structures 52 in the upper wiring dielectric layer 51. The upper wiring dielectric layer 51 may be provided on the second substrate 22. The upper wiring dielectric layer 51 may be provided on a top surface of the second substrate 22 and a bottom surface of the second upper protection layer 24. The upper wiring dielectric layer 51 may include a dielectric material. In some example embodiments, the upper wiring dielectric layer 51 may be a multiple dielectric layer including a plurality of dielectric layers.

The upper conductive structures 52 may be surrounded by the upper wiring dielectric layer 51. Each of the upper conductive structures 52 may be a conductive pad, a conductive line, or a conductive via. The upper conductive structures 52 may be connected to each other. The second through via 27 and the second upper pad 26 may be electrically connected through the upper conductive structures 52. The upper conductive structures 52 may include a conductive material.

The first wiring structure 13 of the first semiconductor die SD1 and the second wiring structure 33 of the second semiconductor die SD2 may each have a structure similar to that of the lower wiring structure 40 or the upper wiring structure 50. The first wiring structure 13 of the first semiconductor die SD1 and the second wiring structure 33 of the second semiconductor die SD2 may each include a wiring dielectric layer and conductive structures in the wiring dielectric layer.

Referring to FIG. 4, the stiffener ST may include first parts ST1 that extend in the first direction D1 and second parts ST2 that extend in the second direction D2. The first parts ST1 of the stiffener ST may be spaced apart from each other in the second direction D2. The first parts ST1 of the stiffener ST may be provided therebetween with the first semiconductor die SD1 and the second parts ST2 of the stiffener ST. The second parts ST2 of the stiffener ST may be spaced apart from each other in the first direction D1. The second parts ST2 of the stiffener ST may be provided therebetween with the first semiconductor die SD1 and the first parts ST1 of the stiffener ST. A lower portion of the first semiconductor die SD1 may be surrounded by the first and second parts ST1 and ST2 of the stiffener ST.

The first part ST1 of the stiffener ST may overlap in the third direction D3 with the third dummy die DD3 or the fourth dummy die DD4. In some example embodiments, a portion of the first part ST1 of the stiffener ST may overlap in the third direction D3 with a portion of the third dummy die DD3 or a portion of the fourth dummy die DD4.

The second part ST2 of the stiffener ST may overlap in the third direction D3 with the first, third, and fourth dummy dies DD1, DD3, and DD4 or the second, third, and fourth dummy dies DD2, DD3, and DD4. In some example embodiments, a portion of the second part ST2 of the stiffener ST may overlap in the third direction D3 with a portion of each of the first, third, and fourth dummy dies DD1, DD3, and DD4 or a portion of each of the second, third, and fourth dummy dies DD2, DD3, and DD4.

The stiffener ST may not overlap in the third direction D3 with any of the first and second semiconductor dies SD1 and SD2. The stiffener ST may be spaced apart in the first direction D1 and the second direction D2 from the first semiconductor die SD1 and the second semiconductor die SD2. The first and second parts ST1 and ST2 of the stiffener ST may overlap in the third direction D3 with the interposer IN, the second molding layer MD2, and the first molding layer MD1.

In the semiconductor package according to some example embodiments, as the interposer IN and the first semiconductor die SD1 are hybrid-bonded, heat transfer between the first semiconductor die SD1 and the interposer IN may be improved to effectively discharge heat generated from the first semiconductor die SD1.

In the semiconductor package according to some example embodiments, as the interposer IN is provided between the first and second semiconductor dies SD1 and SD2, and as the interposer IN has an increased width, heat released from the first semiconductor die SD1 may effectively spread in the interposer IN, and the semiconductor may improve in thermal radiation properties.

In the semiconductor package according to some example embodiments, as the first, second, third, and fourth dummy dies DD1, DD2, DD3, and DD4 are included, heat may be outwardly discharged from the interposer IN through the first, second, third, and fourth dummy dies DD1, DD2, DD3, and DD4, and the semiconductor package may improve in thermal radiation properties.

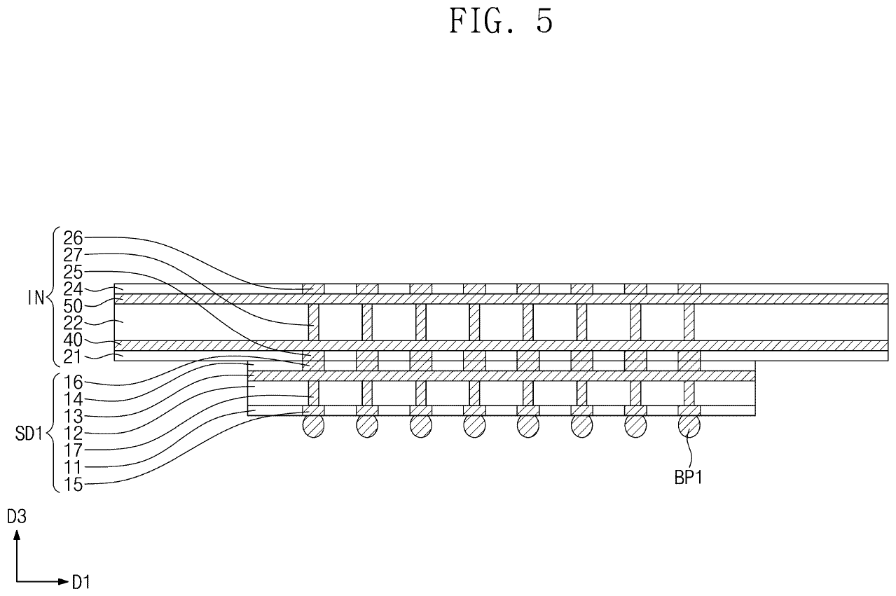

FIGS. 5, 6, 7, and 8 illustrate cross-sectional views showing a method of fabricating a semiconductor package according to some example embodiments.

Referring to FIG. 5, a first semiconductor die SD1 may be connected to a bottom surface of an interposer IN. The interposer IN and the first semiconductor die SD1 may be connected by a hybrid wafer bonding process. A bottom surface of a second lower pad 25 may be allowed to contact a top surface of a first upper pad 16. A bottom surface of a second lower protection layer 21 may be allowed to contact a top surface of a first upper protection layer 14.

First bumps BP1 may be formed on a bottom surface of the first semiconductor die SD1.

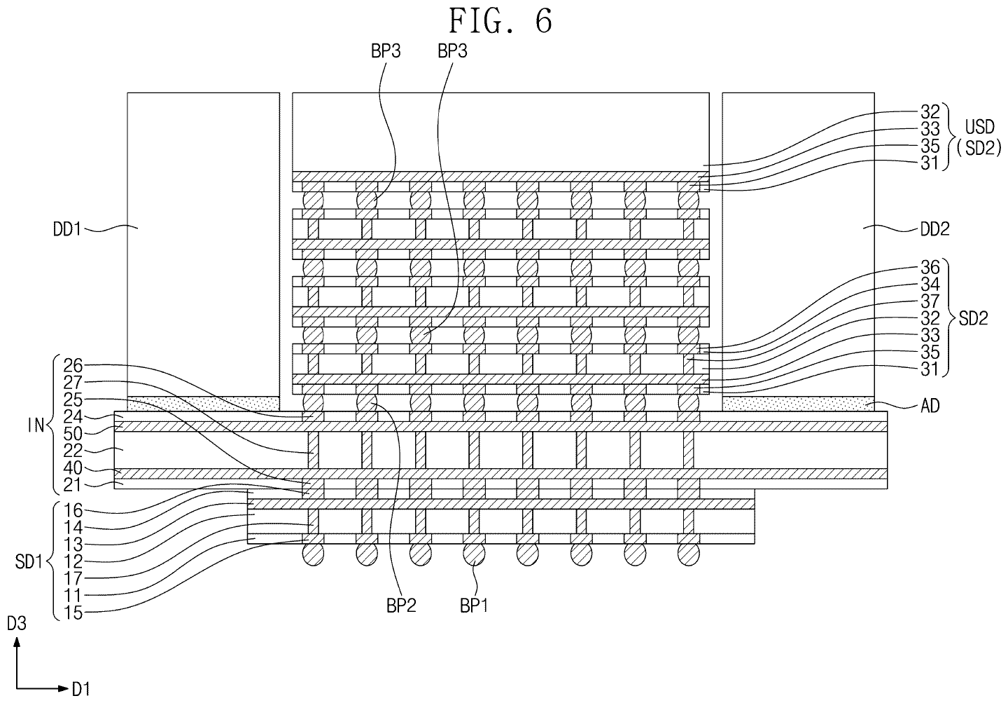

Referring to FIG. 6, second semiconductor dies SD2 may be connected to a top surface of the interposer IN. In some example embodiments, third bumps BP3 may be used to connect the second semiconductor dies SD2 to each other, and then second bumps BP2 may be used to connect the second semiconductor dies SD2 to the interposer IN.

First, second, third, and fourth dummy dies DD1, DD2, DD3, and DD4 may be connected to the top surface of the interposer IN. In some example embodiments, an adhesive layer AD may be formed on a bottom surface of each of the first, second, third, and fourth dummy dies DD1, DD2, DD3, and DD4, and then the adhesive layer AD may be allowed to contact the interposer IN.

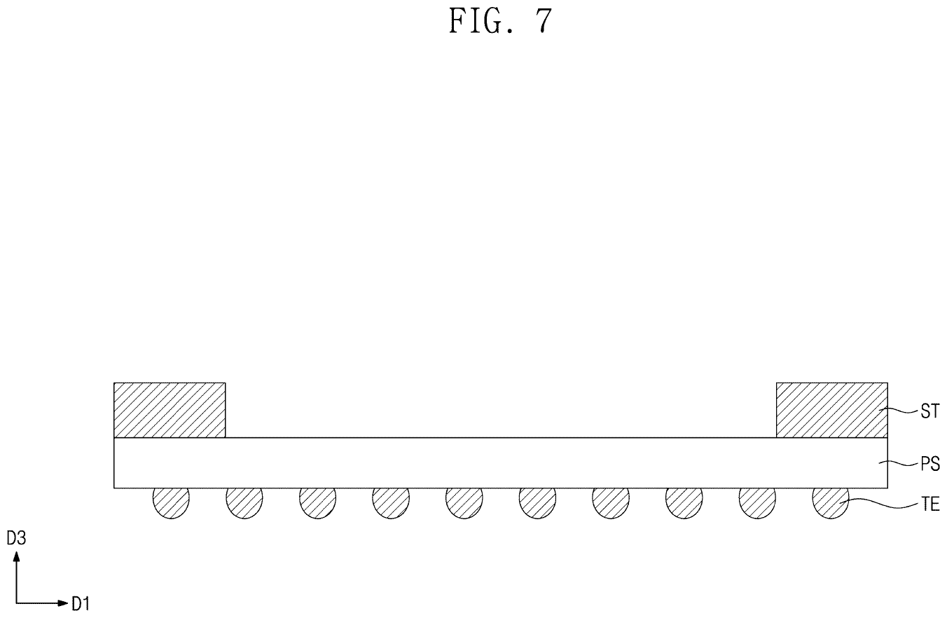

Referring to FIG. 7, a stiffener ST may be formed on a package substrate PS. Terminals TE may be formed on a bottom surface of the package substrate PS.

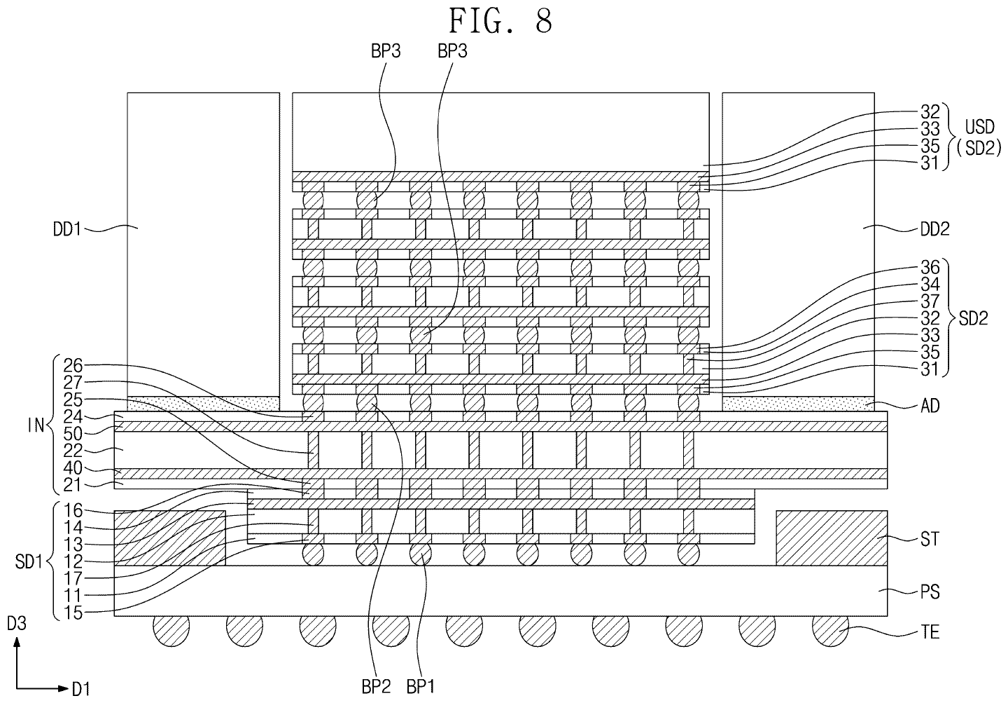

Referring to FIG. 8, the first semiconductor die SD1 may be connected to a top surface of the package substrate PS. First bumps BP1 may be allowed to contact the top surface of the package substrate PS.

Referring to FIG. 2, a first molding layer MD1 may be formed. The first molding layer MD1 may fill a space between the stiffener ST and the interposer IN, a space between the stiffener ST and the first semiconductor die SD1, and a space between the package substrate PS and the first semiconductor die SD1.

A second molding layer MD2 may be formed. The second molding layer MD2 may fill spaces between the second semiconductor dies SD2 and the first, second, third, and fourth dummy dies DD1, DD2, DD3, and DD4.

In some example embodiments, the first molding layer MD1 and the second molding layer MD2 may be formed by one process. In some example embodiments, the first molding layer MD1 and the second molding layer MD2 may be formed by individual processes.

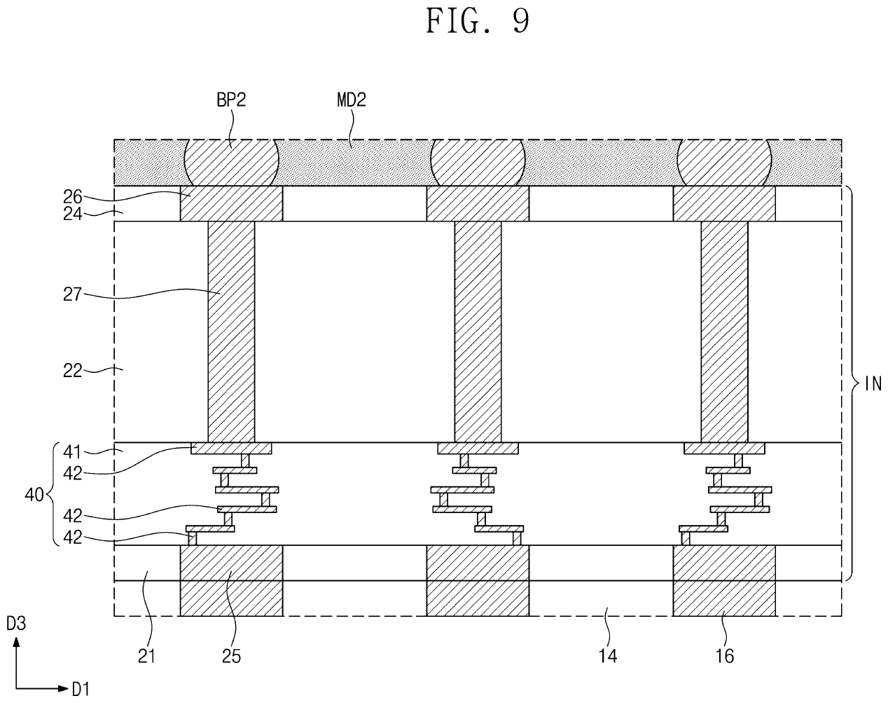

FIG. 9 illustrates an enlarged cross-sectional view showing a semiconductor package according to some example embodiments. Except that discussed below, a semiconductor package of FIG. 9 may be similar to the semiconductor package of FIGS. 1 to 4.

Referring to FIG. 9, the interposer IN may not include an upper wiring structure between the second substrate 22 and the second upper protection layer 24. A top surface of the second substrate 22 may be in contact with a bottom surface of the second upper protection layer 24. A top surface of the second through via 27 may be in contact with a bottom surface of the second upper pad 26.

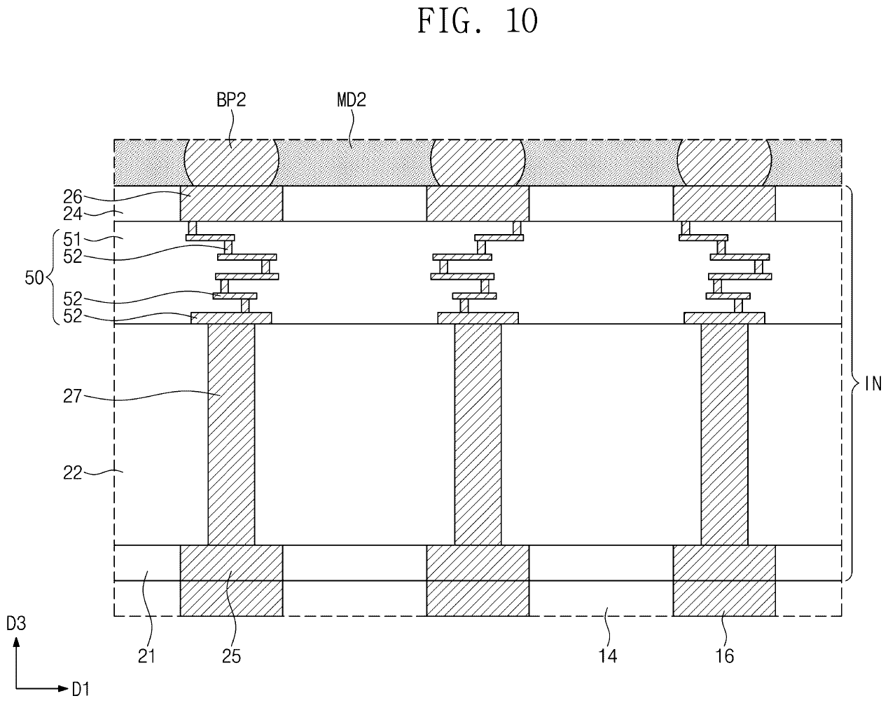

FIG. 10 illustrates an enlarged cross-sectional view showing a semiconductor package according to some example embodiments. Except that discussed below, a semiconductor package of FIG. 10 may be similar to the semiconductor package of FIGS. 1 to 4.

Referring to FIG. 10, the interposer IN may not include a lower wiring structure between the second substrate 22 and the second lower protection layer 21. A top surface of the second lower protection layer 21 may be in contact with a bottom surface of the second substrate 22. A top surface of the second lower pad 25 may be in contact with a bottom surface of the second through via 27.

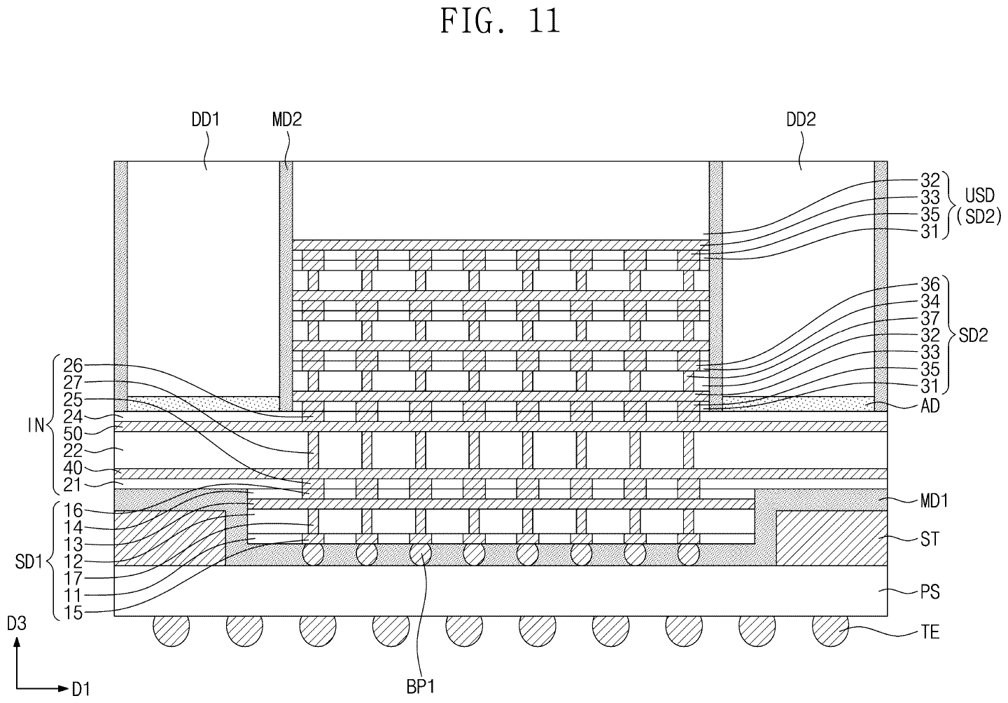

FIG. 11 illustrates a cross-sectional view showing a semiconductor package according to some example embodiments. Except that discussed below, a semiconductor package of FIG. 11 may be similar to the semiconductor package of FIGS. 1 to 4.

Referring to FIG. 11, the second semiconductor dies SD2 may be hybrid-bonded to each other. The third upper pad 36 may be in contact with the third lower pad 35. The third upper protection layer 34 may be in contact with the third lower protection layer 31.

A lowermost one of the second semiconductor dies SD2 may be hybrid-bonded to the interposer IN. The third lower pad 35 of the lowermost second semiconductor die SD2 may be in contact with the second upper pad 26 of the third lower pad 35. The third lower protection layer 31 of the lowermost second semiconductor die SD2 may be in contact with the second upper protection layer 24.

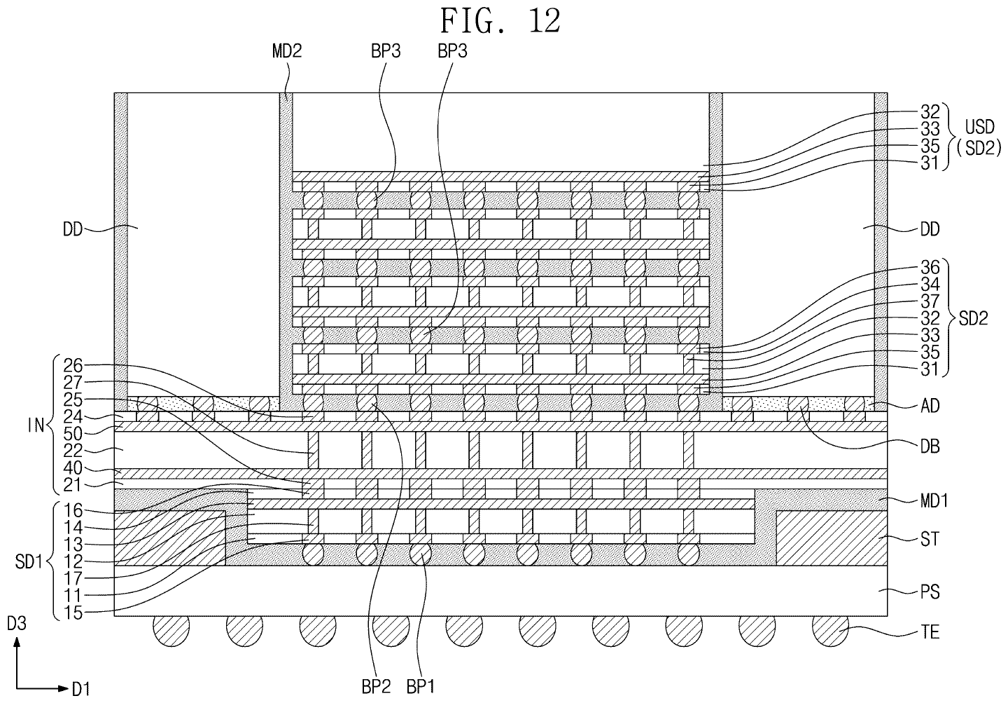

FIG. 12 illustrates a cross-sectional view showing a semiconductor package according to some example embodiments. Except that discussed below, a semiconductor package of FIG. 12 may be similar to the semiconductor package of FIGS. 1 to 4.

Referring to FIG. 12, dummy bumps DB may be provided between a dummy die DD and the interposer IN. The dummy bump DB may be in contact with a bottom surface of the dummy die DD and the second upper pad 26 of the interposer IN. The dummy bump DB may penetrate the adhesive layer AD. The adhesive layer AD may surround the dummy bump DB. The dummy bump DB may include a conductive material.

The dummy bump DB may relatively greatly increase a bonding force between the dummy die DD and the interposer IN.

In some example embodiments, the dummy die DD and the interposer IN may be bonded through only the dummy bumps DB without the adhesive layer AD.

In some example embodiments, the dummy die DD may be a logic semiconductor die including a logic semiconductor device or a memory semiconductor die including a memory semiconductor device. In this case, the dummy die DD may be electrically connected through the dummy bumps DB to the interposer IN.

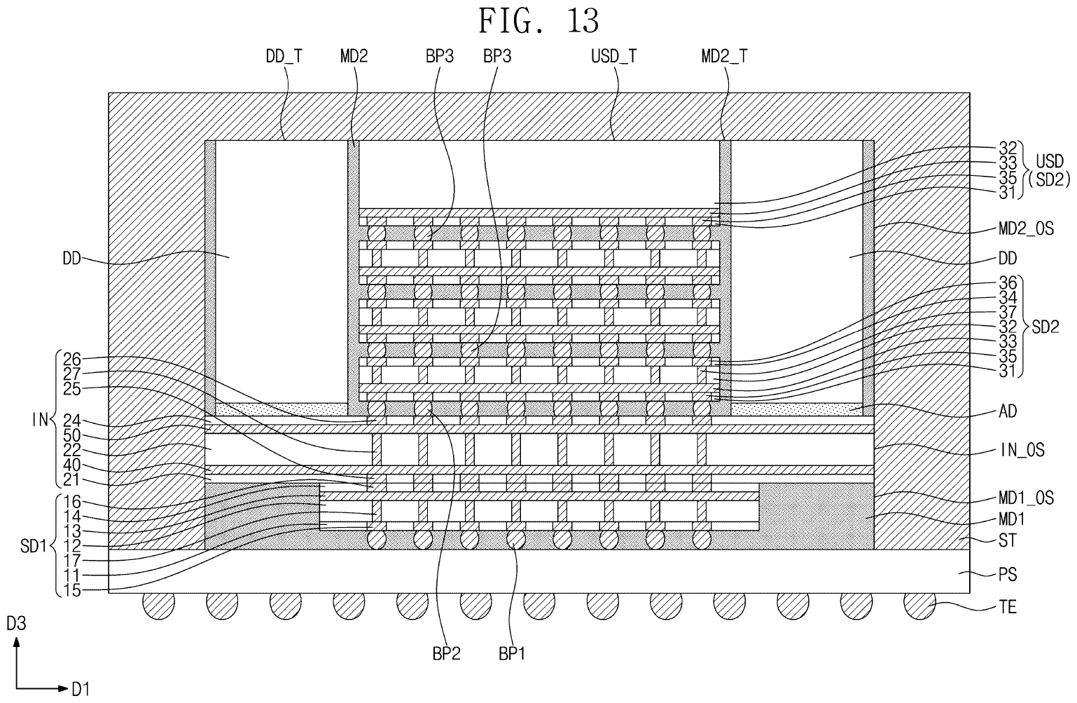

FIG. 13 illustrates a cross-sectional view showing a semiconductor package according to some example embodiments. Except that discussed below, a semiconductor package of FIG. 13 may be similar to the semiconductor package of FIGS. 1 to 4.

Referring to FIG. 13, the stiffener ST may surround the first molding layer MD1, the first semiconductor die SD1, the interposer IN, the second semiconductor dies SD2, the dummy dies DD, and the second molding layer MD2. The stiffener ST may be in contact with a top surface of the package substrate PS, an outer sidewall MD1_OS of the first molding layer MD1, an outer sidewall IN_OS of the interposer IN, an outer sidewall MD2_OS of the second molding layer MD2, a top surface MD2_T of the second molding layer MD2, a top surface DD_T of the dummy die DD, and a top surface USD_T of the uppermost semiconductor die USD. The stiffener ST may serve as a heat slug.

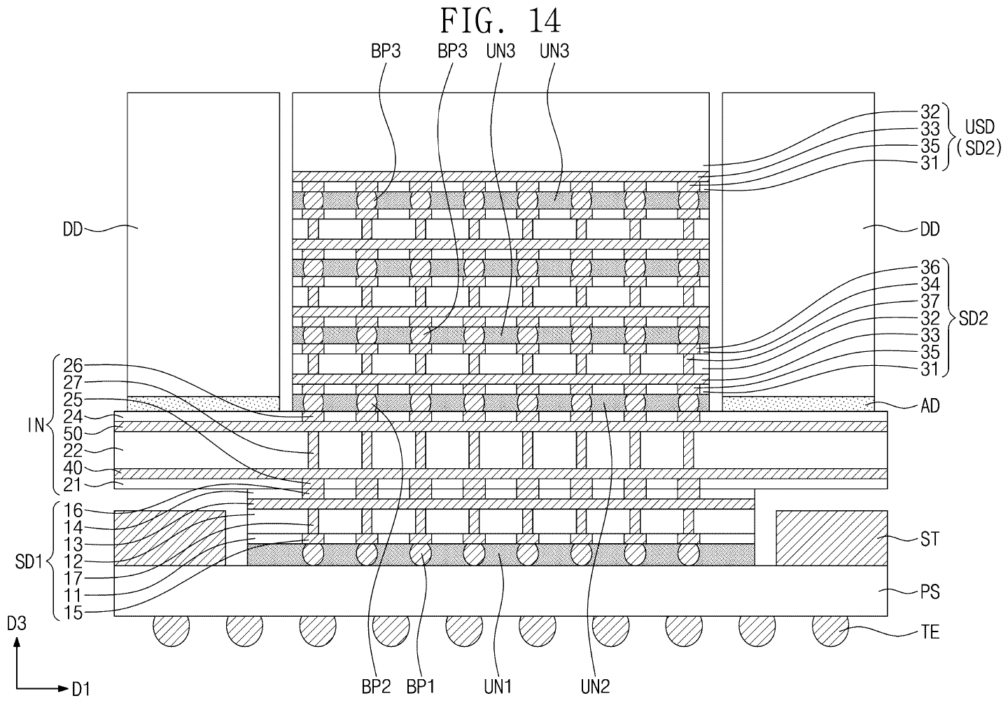

FIG. 14 illustrates a cross-sectional view showing a semiconductor package according to some example embodiments. Except that discussed below, a semiconductor package of FIG. 14 may be similar to the semiconductor package of FIGS. 1 to 4.

Referring to FIG. 14, a semiconductor package may have a chip-on-substrate structure. A first underfill layer UN1 may be provided between the package substrate PS and the first semiconductor die SD1. The first underfill layer UN1 may surround the first bumps BP1. The first underfill layer UN1 may include a polymeric material.

No molding layer may be provided between the package substrate PS and the interposer IN. An empty space may be provided between the package substrate PS and the interposer IN.

A second underfill layer UN2 may be provided between the interposer IN and the second semiconductor die SD2. The second underfill layer UN2 may surround the second bumps BP2. The second underfill layer UN2 may include a polymeric material.

Third underfill layers UN3 may be provided. The third underfill layer UN3 may be provided between the second semiconductor dies SD2. The third underfill layer UN3 may surround the third bumps BP3. The third underfill layer UN3 may include a polymeric material.

No molding layer may be provided between the dummy dies DD and the second semiconductor dies SD2. Empty spaces may be provided between the dummy dies DD and the second semiconductor dies SD2.

In a semiconductor package according to some example embodiments of the present inventive concepts, as an interposer and a logic semiconductor die are hybrid-bonded to each other, heat transfer between the logic semiconductor die and the interposer may be improved to effectively discharge heat generated from the logic semiconductor die.

In a semiconductor package according to some example embodiments of the present inventive concepts, as an interposer is provided between a logic semiconductor die and a memory semiconductor die, and as the interposer has a relatively large width, heat released from the logic semiconductor die may effectively spread in the interposer, and the semiconductor package may improve in thermal radiation properties.

In a semiconductor package according to some example embodiments of the present inventive concepts, as dummy dies are included, heat may be outwardly discharged from an interposer through the dummy dies, and the semiconductor package may improve in thermal radiation properties.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

Although the present inventions have been described in connection with the some example embodiments of the present inventive concepts illustrated in the accompanying drawings, it will be understood by one of ordinary skill in the art that variations in form and detail may be made therein without departing from the spirit and essential feature of the present inventive concepts. The above disclosed example embodiments should thus be considered illustrative and not restrictive.

1. A semiconductor package, comprising:
an interposer;
a first semiconductor die below the interposer; and
a first dummy die, a second dummy die, and a second semiconductor die over the interposer,
the first semiconductor die, the second semiconductor die, the first dummy die, and the second dummy die overlap the interposer,
the first semiconductor die overlap the second semiconductor die, and
the second semiconductor die between the first dummy die and the second dummy die.

2. The semiconductor package of claim 1, wherein the first semiconductor die and the second semiconductor die are electrically connected through the interposer.

3. The semiconductor package of claim 1, further comprising a package substrate below the first semiconductor die.

4. The semiconductor package of claim 3, further comprising a stiffener on the package substrate,
wherein the stiffener surrounds at least a portion of the first semiconductor die.

5. The semiconductor package of claim 1, wherein each of the first dummy die and the second dummy die is a bulk metal block or a bulk silicon block.

6. The semiconductor package of claim 1, further comprising:
a first adhesive layer between the first dummy die and the interposer; and
a second adhesive layer between the second dummy die and the interposer.

7. The semiconductor package of claim 1, wherein a width of the interposer is greater than a sum of a width of the second semiconductor die, a width of the first dummy die, and a width of the second dummy die.

8. The semiconductor package of claim 7, wherein the width of the interposer is greater than a width of the first semiconductor die.

9. The semiconductor package of claim 8, wherein the width of the interposer is 1 mm to 90 mm greater than the width of the first semiconductor die.

10. A semiconductor package, comprising:
an interposer;
a first semiconductor die below the interposer; and
a first dummy die, a second dummy die, and a second semiconductor die over the interposer,
the second semiconductor die between the first dummy die and the second dummy die,
a width of the interposer being greater than a sum of a width of the first dummy die, a width of the second dummy die, and a width of the second semiconductor die,
the width of the interposer being greater than a width of the first semiconductor die.

11. The semiconductor package of claim 10, wherein
the interposer includes a lower protection layer and a lower pad surrounded by the lower protection layer,
the first semiconductor die includes an upper protection layer and an upper pad surrounded by the upper protection layer,
the lower protection layer is in contact with the upper protection layer, and the lower pad is in contact with the upper pad.

12. The semiconductor package of claim 11, wherein the interposer includes:
a lower wiring structure on the lower pad;
a substrate on the lower wiring structure; and
a through via that penetrates the substrate.

13. The semiconductor package of claim 12, wherein
the lower wiring structure includes,
a lower wiring dielectric layer between the lower protection layer and the substrate; and
a lower conductive structure in the lower wiring dielectric layer, and
the lower conductive structure electrically connects the lower pad to the through via.

14. The semiconductor package of claim 10, wherein
the second semiconductor die includes a plurality of second semiconductor dies,
a top surface of an uppermost semiconductor die among the plurality of second semiconductor dies is coplanar with a top surface of the first dummy die and a top surface of the second dummy die.

15. The semiconductor package of claim 10, wherein
the first semiconductor die is a logic semiconductor die, and
the second semiconductor die is a memory semiconductor die.

16. The semiconductor package of claim 10, further comprising:
a package substrate below the first semiconductor die; and
a stiffener on the package substrate,
wherein the stiffener surrounds the first semiconductor die, the interposer, the first dummy die, the second dummy die, and the second semiconductor die.

17. The semiconductor package of claim 10, wherein
the interposer includes an upper protection layer and an upper pad surrounded by the upper protection layer,
the second semiconductor die includes a lower protection layer and a lower pad surrounded by the lower protection layer,
the lower protection layer is in contact with the upper protection layer, and
the lower pad is in contact with the upper pad.

18. The semiconductor package of claim 10, wherein a height of the first dummy die and a height of the second dummy die are greater than a height of the second semiconductor die.

19. A semiconductor package, comprising:
a package substrate;
a stiffener in contact with the package substrate;
a first semiconductor die over the package substrate;
an interposer over the first semiconductor die;
a first dummy die, a second dummy die, a third dummy die, a fourth dummy die, and a plurality of second semiconductor dies over the interposer;
a first molding layer surrounding the first semiconductor die; and
a second molding layer surrounding the first to fourth dummy dies and the second semiconductor dies,
the second semiconductor dies between the first and second dummy dies, and
the first and second dummy dies and the second semiconductor dies between the third and fourth dummy dies.

20. The semiconductor package of claim 19, wherein
the stiffener overlaps the first to fourth dummy dies, and
the stiffener does not overlay any of the first semiconductor die and the second semiconductor dies.

21.-27. (canceled)
